(19) United States
(12) Patent Application Publication
(10) Pub. No.: US 2026/0360984 A1
(43) Pub. Date: Nov. 12, 2026

(54) ANTENNA MODULE AND HIGH-FREQUENCY MODULE

(71) Applicant: LG INNOTEK CO., LTD., Seoul (KR)

(72) Inventors: Jong Min KIM, Seoul (KR); Yu Seon KIM, Seoul (KR); Yong Hwan KIM, Seoul (KR)

(21) Appl. No.: 19/133,017

(22) PCT Filed: Nov. 29, 2023
(86) PCT No.: PCT/KR2023/019410

§ 371 Date: May 27, 2025

(30) Foreign Application Priority Data
Nov. 30, 2022 (KR) 10-2022-0164806

(51) Int. Cl. H01Q 9/04; H01P 1/203; H01Q 1/22; H01Q 21/30; H03H 7/01

(52) U.S. Cl. CPC H01Q 9/0414; H01P 1/20345; H03H 7/0115; H01Q 1/2291; H01Q 21/30

(57) ABSTRACT

An antenna module disclosed in an embodiment of the invention comprises: a substrate to which a first antenna is coupled; a low-pass filter portion embedded in a portion of the substrate; and a first transmission line connecting a first antenna and the low-pass filter portion, wherein the low-pass filter portion comprises a first conductive layer having first to third patterns, a second conductive layer having a ground pattern having first to third vias and a gap, a third conductive layer having a fourth pattern opposite the first pattern and a fifth pattern opposite the third pattern, a fourth conductive layer having sixth and seventh patterns in a line shape, and first to third dielectric layers between the first to fourth conductive layers. The first pattern and the third pattern of the first conductive layer, the fourth and fifth patterns of the third conductive layer, and the first and second dielectric layers form first and second capacitors, and the second, sixth, and seventh patterns have a line shape and may form first to third inductors.

### TECHNICAL FIELD

An invention relates to an antenna module having WiFi and Bluetooth antenna and a high-frequency module having the same.

### BACKGROUND ART

Bluetooth communication is a series of chips and antenna, and refers to a device that communicates at a range of about 10 to 100 meters in a band of about 2.4 to 2.5 GHz according to the Bluetooth wireless interface standard. Wi-Fi (Wireless Fidelity) refers to a device that communicates at a range of about 2.4 to 2.5 GHz or 5 GHz, such as a short-distance communication device, and allows wireless Internet access using radio waves or infrared transmission methods in a place where a wireless access point (AP) is installed, or allows direct connection (Wi-Fi Direct) with other Wi-Fi modules in a P2P concept.

These Bluetooth and Wi-Fi modules were previously configured as independent (individual) modules and installed in electronic products. Accordingly, when it was necessary to install both BT and Wi-Fi modules in a specific electronic product, various problems could arise in terms of product miniaturization, system stability, etc. The Bluetooth and Wi-Fi modules are both devices that communicate via RF signals, and there are components that may be included in common with each other. However, when configuring independent modules, these components may be used redundantly. Therefore, it can hinder product miniaturization, cause social waste of electronic components, and cause instability in the system due to the redundant configuration of components.

In addition, while Bluetooth uses a channel that overlaps with the channel of Wi-Fi, it does not use the 5~6 GHz band. Therefore, a Bluetooth antenna requires a filter that can filter the 5~6 GHz band, but if the circuit is configured using passive components, the size can increase and price competitiveness can decrease.

### DISCLOSURE

### Technical Problem

An embodiment of the invention provides a novel antenna module capable of solving the above problems. An embodiment of the invention provides an antenna module having a Bluetooth filter built into a substrate without using passive components. An embodiment of the invention provides an antenna module having a low-pass filter built into a substrate and connected to a Bluetooth antenna without using passive components.

### Technical Solution

An antenna module according to an embodiment of the invention comprises: a substrate to which a first antenna is coupled; a low-pass filter portion embedded in a portion of the substrate; and a first transmission line connecting the first antenna and the low-pass filter portion, wherein the low-pass filter portion includes first to fourth conductive layers, and first to third dielectric layers respectively disposed between the first to fourth conductive layers, wherein the first conductive layer includes a first pattern having a first via, a second pattern connected between one end of the first pattern and a second via, and a third pattern connected to the third via, wherein the second conductive layer has a ground pattern having a gap with the first to third vias inside, wherein the third conductive layer includes a fourth pattern facing the first pattern, and a fifth pattern spaced apart from the fourth pattern and facing the second via and the third pattern, wherein the fourth conductive layer includes a sixth pattern connected between the second via inside and a ground via, and a seventh pattern connected between the second via and the third via, wherein the first pattern and the third pattern of the first conductive layer, the fourth pattern and the fifth pattern of the third conductive layer, and the first and second dielectric layer form first and second capacitors, and the second pattern, the sixth pattern, and the seventh pattern have a line shape and may form first to third inductors.

According to an embodiment of the invention, the first pattern and the third pattern of the first conductive layer, and the fourth pattern and the fifth pattern of the third conductive layer may have a polygonal plate shape.

According to an embodiment of the invention, an upper surface area of the fifth pattern may be smaller than an upper surface area of the third pattern and larger than an upper surface area of the first pattern. The upper surface area of the third pattern may be smaller than the upper surface area of the first pattern.

According to an embodiment of the invention, the first conductive layer may include a first input/output pattern connected to the other end of the first pattern and the first transmission line, and a second input/output pattern connected to the second pattern and the second transmission line of the other side of the low-pass filter portion.

According to an embodiment of the invention, a length of the sixth pattern may be longer than a length of the second pattern. A number of bends of the sixth pattern may be greater than a number of bends of the second and seventh patterns.

According to an embodiment of the invention, the first capacitor may have a first capacitance by the first dielectric layer between the first pattern of the first conductive layer and a first circular pattern connected to the first via of the second conductive layer, and a second capacitance by the second dielectric layer between the first circular pattern and the fourth pattern.

According to an embodiment of the invention, the second capacitor may be connected to the fifth pattern, the third circular pattern connected to the third via of the second conductive layer, and the third pattern of the first conductive layer through the third via connected to the seventh pattern of the fourth conductive layer, and the second capacitor may include a third capacitance between the third circular pattern and the fourth pattern, and a fourth capacitance by the first dielectric layer between the fifth pattern and the third circular pattern.

According to an embodiment of the invention, the second capacitor may include a fifth capacitance by the first dielectric layer between the first via of the first conductive layer and a second circular pattern connected to the second via of the second conductive layer, and a sixth capacitance by a second dielectric layer between the second circular pattern and a fourth circular pattern connected to the second via of the third conductive layer. The third and fifth capacitances may be connected in parallel with each other, and the fourth and sixth capacitances may be connected in parallel with each other.

According to an embodiment of the invention, the low-pass filter portion may include a Wi-Fi module connected to a second transmission line; and a second antenna connected to the Wi-Fi module, wherein the first antenna may be a Bluetooth antenna, and the second antenna may be a Wi-Fi antenna. The low-pass filter portion may pass a 2402 to 2480 MHz band and filter a 5 to 6 GHz band.

A high-frequency module according to an embodiment of the invention includes a low-pass filter portion in which a first input/output pattern is electrically connected to a Bluetooth antenna and a second input/output pattern is electrically connected to a Wi-Fi module, wherein the low-pass filter portion includes first to fourth conductive layers, dielectric layers respectively disposed between the first to fourth conductive layers, and a plurality of vias that penetrate vertically through the first to fourth conductive layers and the dielectric layers and selectively connect patterns of different conductive layers, the dielectric layers disposed between one-side patterns of the first to third conductive layers and one-side patterns of the first to third conductive layers face each other and form a first capacitor connected in parallel to a first branch node connected to a first input/output pattern, a first line pattern of the first conductive layer forms a first inductor connected in series to the first branch node, a second line pattern of the fourth conductive layer forms a second inductor connected in parallel from a third branch node connected to the other end of the first inductor, a third line pattern of the fourth conductive layer forms a third inductor connected in parallel from the second branch node connected to the second input/output pattern and the third branch node, the dielectric layers disposed between the other side patterns of the first to third conductive layers and the other-side patterns of the first to third conductive layers face each other and form a second capacitor connected in series to the third inductor, and the other end of the first capacitor, the other end of the second inductor, and the other end of the second capacitor may be connected to a ground pattern.

According to an embodiment of the invention, the low-pass filter portion may pass a band of 2402 to 2480 MHz and filter a band of 5 to 6 GHz. Each of the first to third branch nodes may be formed by a via arranged within the low-pass filter portion.

### Advantageous Effects

The invention can reduce a size of the antenna module by incorporating a filter into the substrate without using inductor and capacitor components. It can also reduce the cost of the antenna module. In addition, by connecting a low-pass filter (LPF) built into the substrate of the antenna module to the Bluetooth antenna, the 5 to 6 GHz band may be filtered, and the insertion loss characteristic of the 5 to 6 GHz band may be configured to satisfy −3 dB or less.

### DESCRIPTION OF DRAWINGS

FIG. 1 is a block diagram of an antenna module according to an embodiment of the invention.

FIG. 2 is a plan view showing a part of the antenna module of FIG. 1.

FIG. 3 is a perspective view showing a low-pass filter portion of FIG. 2.

FIG. 4 is another side view of the low-pass filter portion of FIG. 3.

FIG. 5 is an example of a circuit configuration of a low-pass filter according to the present invention.

FIG. 6 is an exploded perspective view of the low-pass filter portion of FIG. 3.

FIG. 7 is a drawing showing the pattern shape of the first to fourth conductive layers of the low-pass filter portion of FIG. 6.

FIG. 8 is an example of an A-A side cross-section of the low-pass filter portion of FIG. 3.

FIG. 9 is an example of a B-B side cross-section of the low-pass filter portion of FIG. 3.

FIG. 10 is a graph showing the operating characteristics of the low-pass filter portion of the antenna module according to an embodiment of the invention.

### BEST MODE

Hereinafter, an antenna module according to an embodiment of the present invention will be described in detail with reference to the attached drawings. The described embodiments are provided so that those skilled in the art can easily understand the technical idea of the present invention, but the present invention is not limited thereby. In addition, matters expressed in the attached drawings are schematic drawings for easily explaining embodiments of the present invention and may be different from the form actually implemented. In the specification, the singular also includes the plural unless specifically stated in the phrase. The terms “comprises” and/or “comprising” as used in the specification do not exclude the presence or addition of one or more other components, steps, operations, and/or elements mentioned.

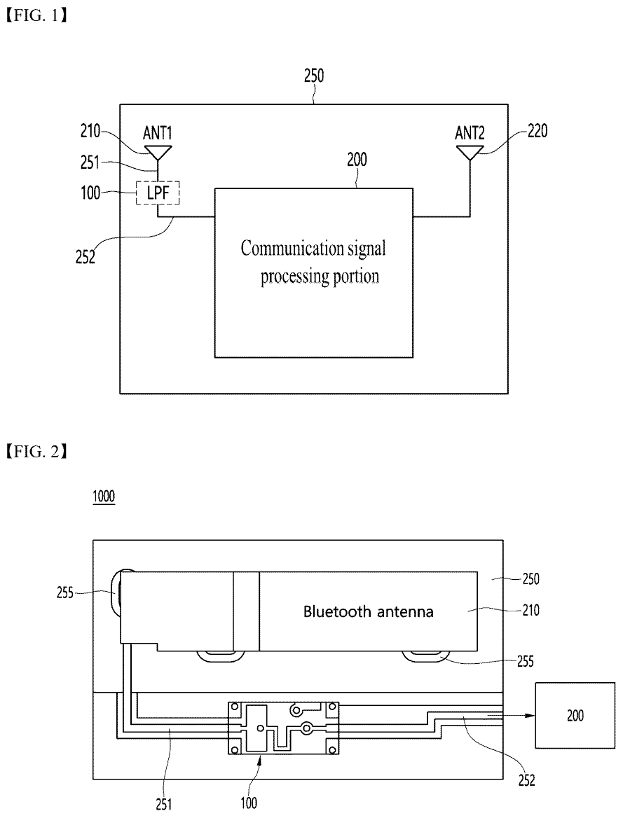

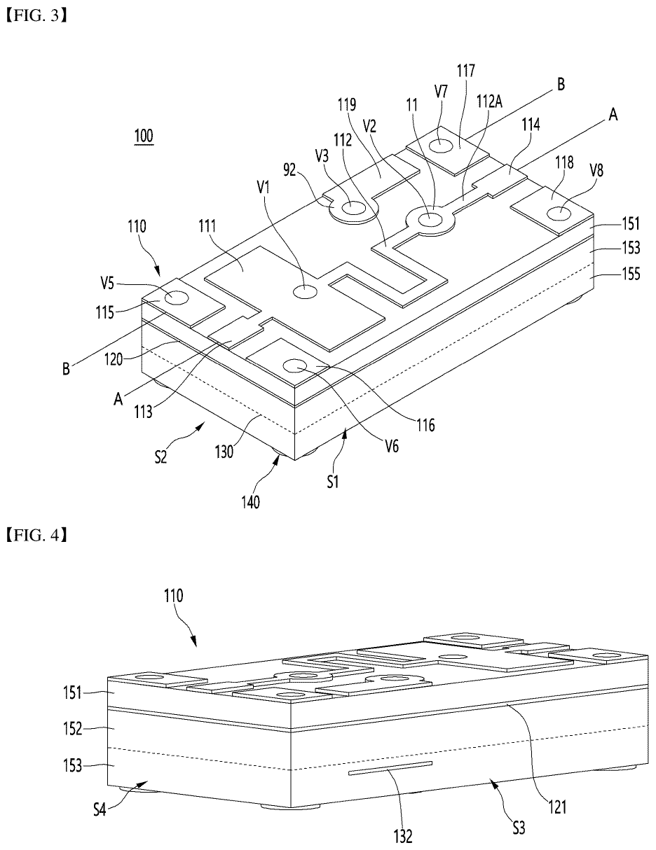

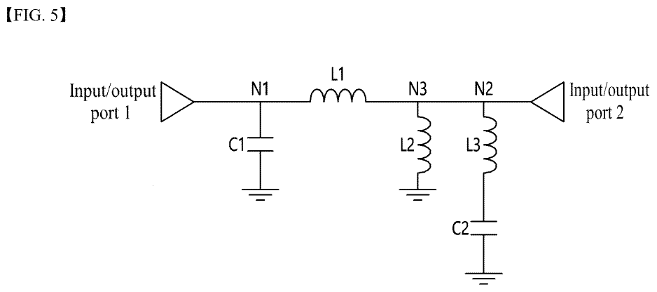

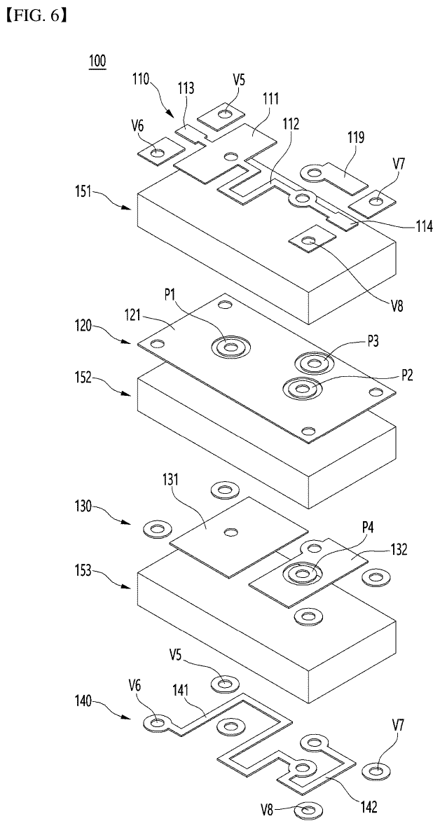

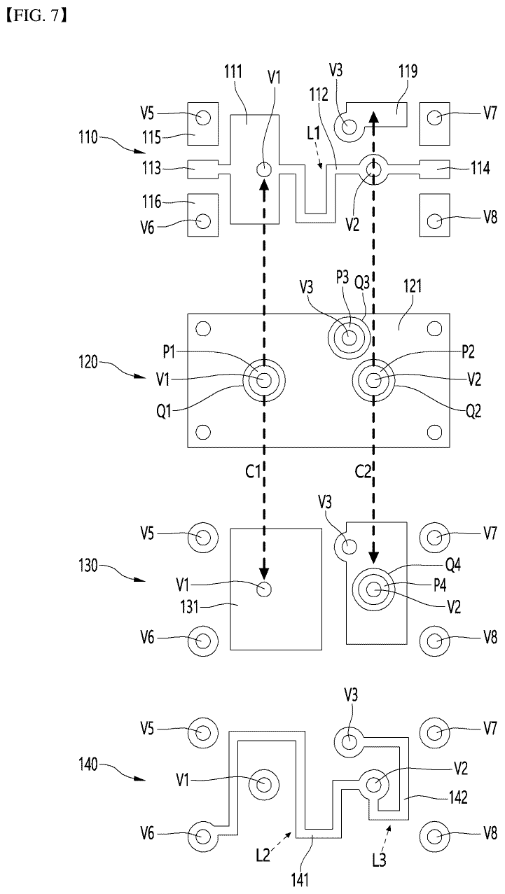

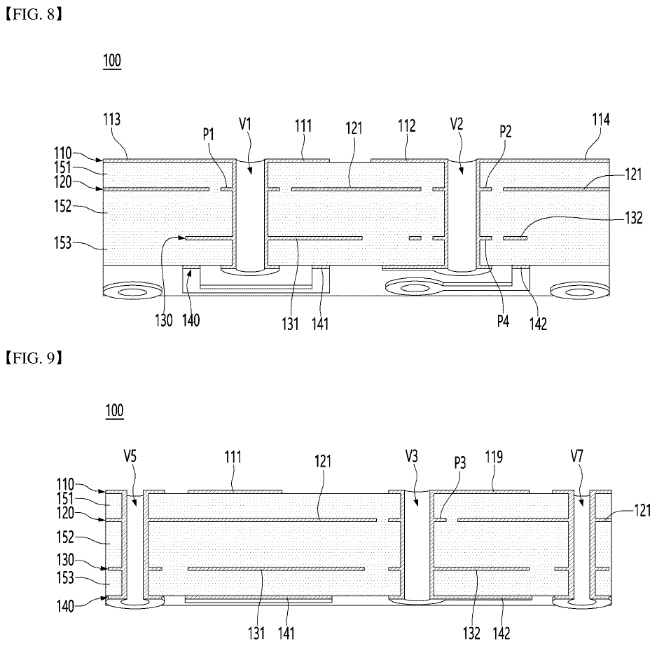

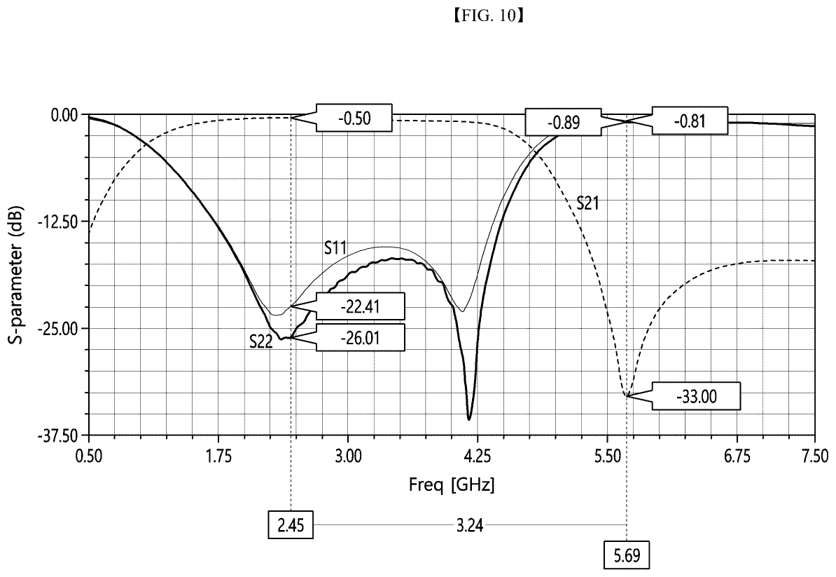

FIG. 1 is a block diagram of an antenna module according to an embodiment of the invention, FIG. 2 is a plan view showing a part of the antenna module of FIG. 1, FIG. 3 is a perspective view showing a low-pass filter portion of FIG. 2, FIG. 4 is another side view of the low-pass filter portion of FIG. 3, FIG. 5 is an example of a circuit configuration of a low-pass filter portion according to the present invention, FIG. 6 is an exploded perspective view of the low-pass filter portion of FIG. 3, FIG. 7 is a drawing showing a pattern shape of first to fourth conductive layers of the low-pass filter portion of FIG. 6, FIG. 8 is an example of an A-A side cross-section of the low-pass filter portion of FIG. 3, FIG. 9 is an example of a B-B side cross-section of the low-pass filter portion of FIG. 3, and FIG. 10 is a graph showing the operating characteristics of the low-pass filter portion of the antenna module according to an embodiment of the invention.

Referring to FIG. 1, an antenna module includes a first antenna 210 for transmitting and receiving a first high-frequency signal, a low-pass filter portion 100 connected to a transmission line 251 and 252 of the first antenna 210, a second antenna 220 for transmitting and receiving a second high-frequency signal, and a communication signal processing portion 200 for generating and processing transmission/reception signals of the first and second antennas 210 and 220.

The first antenna 210 is a Bluetooth antenna, the second antenna 220 is a Wi-Fi antenna, and the communication signal processing portion 200 may be implemented as a Wi-Fi module. The first high-frequency signal includes a Bluetooth signal, for example, a band of 2402 to 2480 MHz. The second high-frequency signal includes a Wi-Fi signal, for example, a band of 2400 to 2483 MHz and 5 to 6 GHz. Here, the first high-frequency signal uses a channel that overlaps with the low frequency band (e.g., 2402 to 2480 MHz) of the second high-frequency signal, and does not use a channel that overlaps with the high frequency band (e.g., 5 to 6 GHz).

As shown in FIGS. 2 to 4, the low-pass filter portion 100 is connected to the transmission lines 251 and 252 between the first antenna 210 and the communication signal processing portion 200, and may pass the low frequency band and filter the high frequency band. The low-pass filter portion 100 may be connected between the first transmission line 251 connected to the first antenna 210 and the second transmission line 252 connected to the communication signal processing portion 200. The first and second transmission lines 251 and 252 are feed lines that feed signals.

The low-pass filter portion 100 may form a resonant circuit using an inductor and a capacitor, and the inductor and capacitor may be implemented by a pattern of a conductive layer and a dielectric layer, rather than passive components. Accordingly, since passive components are not used, cost reduction is possible, and a size of the low-pass filter portion 100 may be reduced.

The first and second antennas 210 and 220 may be coupled to the substrate 250. The first antenna 210 may be coupled to a coupling portion 255 of the substrate 250, and the coupling portion 255 may be a coupling hole to which a lower coupling protrusion of the first antenna 210 is fastened. One of the coupling portions 255 of the substrate 250 may be connected to the first transmission line 251. In addition, the low-pass filter portion 100 may be embedded in the substrate 250 of the communication signal processing portion 200. The substrate 250 may be a multilayer substrate having a plurality of conductive layers.

As shown in FIG. 5, a circuit configuration of the low-pass filter portion 100 is implemented as a passive filter having a first input/output port and a second input/output port for transmitting and receiving signals, and a first capacitor C1 is connected in parallel to a first branch node N1 connected to the first input/output port, and the other end of the first capacitor C1 is grounded. One end of a first inductor N1 is connected in series to the first branch node N1, and a third branch node N3 is connected to the other end of the first inductor N1, and one end of a second inductor L2 is connected in parallel to the third branch node N3, and the other end of the second inductor L2 is grounded.

A second branch node N2 connected to the second input/output port has one end of a third inductor L3 connected in parallel, and the other end of the third inductor L3 is connected in series with a second capacitor C2, and the other end of the second capacitor C2 is connected to ground. The second branch node N2 is connected in series with the third branch node N3. Here, the first input/output port may be connected to the first transmission line 251 or may be formed integrally with it. The second input/output port may be connected to the second transmission line 252 or may be formed integrally with it. The low-pass filter portion 100 passes a first frequency band (e.g., 2400 to 2483 MHz) transmitted to the first and second input/output ports, and filters a second frequency band (e.g., 5 to 6 GHz).

The first to third inductors L1, L2, and L3 may have a range of 0.5 to 4 nH and may have different inductances. For example, the first inductor L1 may have a range of 1.3 nH±0.2 nH, the second inductor L2 may have 2.7 nH±0.2 nH, and the third inductor L3 may have 1.5 nH±0.2 nH. The first and second capacitors C1 and C2 may have a range of 0.3 to 2.5 pF and may be different from each other. The first capacitor C1 may have, for example, 0.9 pF±0.05 pF, and the second capacitor C2 may have 0.5 pF±0.01 pF.

As shown in FIGS. 3, 4, 6 to 9, the low-pass filter portion 100 may be a part of the substrate 250 of FIG. 2 or a substrate region embedded in the substrate 250. The low-pass filter portion 100 may include a plurality of conductive layers 110, 120, 130, and 140 and a plurality of dielectric layers 151, 152, and 153 respectively disposed between the plurality of conductive layers 110, 120, 130, and 140. The plurality of conductive layers 110, 120, 130, and 140 may be made of copper or may be a layer in which at least one plating layer is laminated on the surface of the copper material. The plating layer may include at least one of nickel, gold, tin, lead, palladium, silver, and a mixture thereof.

The material of the dielectric layers 151, 152, and 153 may include at least one of insulating materials, such as FR-4, CEM-1, RF-35, Teflon, polyimide, and PTEE (Polytetrafluoroethylene). The dielectric layers 151, 152, and 153 may include dielectrics of capacitors, such as Ta₂O₅, BaO₄SrTi, and TiO₂, and BaO, Al₂O₃, PbO, CaO, and B₂O₃. The above-described plurality of conductive layers 110, 1201, 130, and 140 may include first to fourth conductive layers 110, 1201, 130, and 140 laminated from the upper surface to the lower surface of the substrate 250, and the above-described plurality of dielectric layers 151, 152, and 153 may include first to third dielectric layers 151, 152, and 153 respectively disposed between the first to fourth conductive layers 110, 1201, 130, and 140. The first and second dielectric layers 151 and 152 may include a dielectric of the capacitor, and the thickness of the second dielectric layer 152 may be greater than the thickness of the first dielectric layer 151. For example, the thickness of the first and third dielectric layers 151 and 153 may be formed to be 300 μm or less, for example, in the range of 100 to 300 μm, and the thickness of the second dielectric layer 152 may be formed to be 300 μm or more, for example, in the range of 300 to 500 μm.

The first dielectric layer 151 is arranged between the first conductive layer 110 and the second conductive layer 120, the second dielectric layer 152 is disposed between the second conductive layer 120 and the third conductive layer 130, and the third dielectric layer 153 is disposed between the third conductive layer 130 and the fourth conductive layer. The first conductive layer 110 may be exposed on the upper surface of the substrate, and the fourth conductive layer 140 may be exposed on the lower surface.

As shown in FIGS. 3 and 4, the low-pass filter portion 100 may have a width between the first side surface S1 and the third side surface S3 smaller than the length between the second side surface S2 and the fourth side surface S4. Accordingly, a conductive pattern of an inductor having a long length may be arranged in a first direction (e.g., length direction) from the second side surface S2 toward the fourth side surface S4. In addition, a conductive pattern of an inductor having a short length may be arranged in a second direction (e.g., width direction) from the first side surface S1 toward the third side surface S3. The first conductive layer 110 may be exposed to the upper surface of the substrate, and the fourth conductive layer 140 may be exposed to the lower surface of the substrate. As shown in FIG. 4, a part of the pattern 132 of the second conductive layer 140 may be exposed to the side surface S3.

As shown in FIG. 4 and FIG. 6, the first conductive layer 110 includes a first pattern 111, a second pattern 112, and a third pattern 119, the second conductive layer 120 has a ground pattern 121, the third conductive layer 130 includes a fourth pattern 131 and a fifth pattern 132 that are spaced apart from each other, and the fourth conductive layer 140 may include a sixth pattern 141 and a seventh pattern 142 connected to the first via V2. The first pattern 111 and the second pattern 112 of the first conductive layer 110 are connected to the first via V1 and the first via V2 spaced apart in the first direction, and the first pattern 111 is a plate-shaped pattern having a polygonal shape, and the second pattern 112 is a line-shaped pattern having a narrower width than the width of the plate-shaped pattern. The first pattern 111 has a first via V1 therein and is connected to one end of the second pattern 112, and the other end of the second pattern 112 is connected to the first via V2. The second pattern 112 has a folded structure, and for example, has a folded structure of two or more or three or more times. The second pattern 112 may increase or decrease the value of the inductance depending on the folded shape and length. The length of the second pattern 112 and L1 may be in the range of 0.5 to 3 mm. Here, the length of the second pattern 112 and L1 is a length extended from one end to the other end. The width of the second pattern 112 and L1 may be in the range of 10 to 200 μm.

One end of the first pattern 111 is connected to the second pattern 112, the other end is connected to the first input/output pattern 113, and the second pattern 112 and the second via V2 are connected to the second input/output pattern 114. The first and second input/output patterns 113 and 114 are the first and second input/output ports. The second via V2 has a circular pattern around it, and the diameter of the circular pattern may be larger than the width of the second pattern 112.

The third pattern 119 is a plate-shaped pattern having a third via V3, and may be spatially spaced from the first and second patterns 111 and 112. The third pattern 119 may have a polygonal shape. A hemispherical pattern may be formed along one side of the third via V3. The upper surface area of the third pattern 119 may be smaller than the upper surface area of the first pattern 111. The third via V3 is disposed between the fifth via V5 and the seventh via V7 in the first direction, and may be positioned closer to the seventh via V7 than to the fifth via V5. At each corner of the first conductive layer 110, patterns 115, 116, 117, and 118 having fifth to eighth vias V5 to V8 are disposed and are physically separated from the first to third patterns 111, 112, and 119. The patterns 115, 116, 117, and 118 having fifth to eighth vias V5 to V8 in the first conductive layer 110 may have a polygonal shape.

As shown in FIGS. 6 and 7, the second conductive layer 120 is a ground pattern 121, and the ground pattern 121 includes a first circular pattern P1 connected to the first via V1, a second circular pattern P2 connected to the first via V2, and a third circular pattern P3 connected to the third via V3. Each of the first to third circular patterns P1, P2, and P3 may be spaced apart from the ground pattern 121 by a predetermined gap Q1, Q2, and Q3. Each of the first to third circular patterns P1, P2, and P3 is not physically connected to the ground pattern 121. The ground pattern 121 is connected to the fifth to eighth vias V5 to V8, and may have a surface area larger than the surface area of the patterns of the first conductive layer 110 or larger than the surface area of the patterns of the third conductive layer 130.

The third conductive layer 130 includes a fourth pattern 131 connected to the first via V1, a second via V2, and a fifth pattern 132 connected to the third via V3. The fourth pattern 131 and the first pattern 111 of the first conductive layer 110 face each other on both sides of the ground pattern 121. The upper surface area of the fourth pattern 131 may be smaller than the upper surface area of the first pattern 111. The first via V2 disposed in the fifth pattern 132 may have a fourth circular pattern P4 and may be spaced apart from the fifth pattern 132 by a predetermined gap Q4. The fourth circular pattern P4 is not physically connected to the fifth pattern 132. The fifth pattern 132 may be connected to the third pattern 119 on the inside. The fifth pattern 132 and the second and third patterns 111 and 112 face each other on both sides of the ground pattern 121. The fourth pattern 131 and the fifth pattern 132 may be implemented as a plate-shaped pattern having a polygonal shape. The upper surface area of the fourth pattern 131 may be larger than the upper surface area of the first pattern 111 and may be larger than the upper surface area of the fifth pattern 132. In addition, the upper surface area of the fifth pattern 132 may be larger than the upper surface area of the first pattern 111. Here, the polygonal shape may include a square shape.

Fifth to eighth vias V5 to V8 may be arranged at each corner of the third conductive layer 130, and the fifth to eighth vias V5 to V8 of the third conductive layer 130 may have a circular pattern. As shown in FIGS. 8 and 9, the gaps Q1, Q2, Q3, and Q4 may be filled with materials of the dielectric layer. The fourth conductive layer 140 includes a sixth pattern 141 and a seventh pattern 142, and the sixth pattern 141 and the seventh pattern 142 are connected to a first via V2. The sixth pattern 141 is a line pattern, extending between the first via V2 and the sixth via V6, and may have a line shape having a two or more folded structure, for example, may have a four or more bent structure.

The total length of the sixth pattern 141 may be greater than the total length of the second pattern 112. The number of bending of the sixth pattern 141 may be greater than the number of bending of the second pattern 112, for example, may be two or more times more. The length of the sixth pattern 141 and L2 is 3 to 10 mm, and represents the total length. The width of the sixth pattern 141 and L2 is 10 to 200 μm. The seventh pattern 142 is a line pattern, connected between the first via V2 and the third via V3, and may have a line shape having one or more bent structures, for example, two or three or more bent structures. The length of the seventh pattern 142 and L3 is 0.5 to 3 mm, and represents the total length. The width of the seventh pattern 142 and L3 is 10 to 200 μm.

Fifth to eighth vias V5 to V8 may be disposed at each corner of the fourth conductive layer 140, and the fifth to eighth vias V5 to V8 of the fourth conductive layer 140 may have a circular pattern. Here, the first capacitor C1 may include a first capacitance by the first dielectric layer 151 between the first pattern 111 of the first conductive layer 110 and the first circular pattern P1 of the second conductive layer 120, and a second capacitance by the second dielectric layer 152 between the first circular pattern P1 and the fourth pattern 131. The first pattern 111 of the first conductive layer 110 and the fourth pattern 131 of the third conductive layer 130 may function as opposite electrode terminals of the first capacitor. The first and second capacitances may be connected in series. The first inductor L1 is implemented by the second pattern 112 connected between the first pattern 111 and the first via V2. The first inductor L1 may have an inductance value that varies depending on the length and/or area of the first pattern 111. The second pattern 112, the sixth pattern 116, and the seventh pattern 117 may each be line patterns for inductors. The second inductor L2 is implemented as a line-shaped sixth pattern 141 connected between the first via V2 and the sixth via V6 of the fourth conductive layer 140, and the inductance value may vary depending on the length and/or area of the sixth pattern 141. The second inductor L2 may be connected to the ground pattern 121 through the sixth via V6. The inductance value of the sixth pattern 141 may be greater than the inductance value of the second pattern 112. The third inductor L3 is implemented as a line-shaped seventh pattern 142 connected between the first via V2 and the third via V3, and the inductance value may vary depending on the length and/or area of the seventh pattern 142. The inductance value of the seventh pattern 142 may be greater than the inductance value of the second pattern 112.

The second capacitor C2 may be formed by being connected to the fifth pattern 132, the third circular pattern P3, and the third pattern 119 through the third via V3 connected to the seventh pattern 142, and at this time, may have a third capacitance by the first dielectric layer 151 between the third pattern 119 and the third circular pattern P3, and a fourth capacitance by the second dielectric layer 152 between the third circular pattern P3 and the fifth pattern 132. In addition, the second capacitor C2 may have a fifth capacitance by the first dielectric layer 151 between the first via V2 and the second circular pattern P2, and a sixth capacitance by the second dielectric layer 152 between the second circular pattern P2 and the fourth circular pattern P4. The third and fourth capacitances may be connected in series, and the fifth and sixth capacitances may be connected in series. The third and fifth capacitances may be connected in parallel with each other, and the fourth and sixth capacitances may be connected in parallel with each other. Accordingly, the second capacitor C2 may have the third to sixth capacitances by the patterns on both sides of the first and second dielectric layers 151 and 152 and be connected in series to the seventh pattern 142.

Since the area of the first pattern 111 is larger than that of the third pattern 119, and the area of the above fourth pattern 131 is larger than that of the fifth pattern 132, the capacitance of the second capacitor C2 may be smaller than that of the first capacitor C1.

As shown in FIG. 8, a first pattern 111, a second circular pattern P2, and a fourth pattern 131 are connected to a first via V1, and a second pattern 112, a second circular pattern P2, a fourth circular pattern P4, and a sixth pattern 141 are connected to a first via V2. As shown in FIG. 9, a third via V3 is connected to a third pattern 119, a third circular pattern P3, a fifth pattern 132, and a seventh pattern 142. The fifth via V5 is connected to a ground pattern 121, and may be connected to via patterns of the first, third, and fourth conductive layers 110, 130, and 140. The fifth via V5 may not be connected to via patterns of the third and fourth conductive layers 130 and 140. That is, the fifth, seventh, and eighth vias V5, V7, and V8 of the third and fourth conductive layers may be patterns arranged to support between two dielectric layers. The seventh via V7 may be connected to the ground pattern 121 and may be connected to the via patterns of the first, third, and fourth conductive layers 110, 130, and 140. Each of the first to third branch nodes N1, N2, and N3 may be formed by the first to third vias V1, V2, and V3 arranged within the low-pass filter portion 100.

As another example of the invention, the conductive layer/dielectric layer of FIG. 6 may be arranged in reverse, for example, the patterns of the first conductive layer 110 may be arranged in the pattern of the fourth conductive layer, the patterns of the second conductive layer 110 may be arranged in the pattern of the third conductive layer, the patterns of the third conductive layer 130 may be arranged in the pattern of the second conductive layer, and the patterns of the fourth conductive layer 140 may be implemented as patterns of the first conductive layer. That is, the configuration disclosed in FIG. 6 may be embedded in the substrate in an up/down reversed or 180 degree rotated state to implement the patterns of each layer. In this case, the input/output pattern may be arranged in the fourth conductive layer 140 and may be connected to the transmission line 251 and 252 through the lower surface of the substrate 250.

The low-pass filter portion 100 embedded in the substrate as described above may have a frequency response characteristic as shown in FIG. 10. In the S-parameter, S21 represents the insertion loss of the low pass filter, and compares the size of the signal output from the first input/output port to the size of the signal output from the second input/output port. It may be seen that it satisfies the minimum of −3 dB or less in the 5 to 6 GHz band. That is, it may be seen that the low-pass filter portion 100 exhibits a high filtering effect in the 5 to 6 GHz band. The closer the insertion loss is to 0, the better the signal flows. In the S-parameter, S11 represents the reflection coefficient or return loss at the first input/output port, and S22 represents the reflection coefficient or return loss at the second input/output port. The frequencies of the transmission zeros (−22.41, −26.01) in the curves of the S11 and S22 may be adjusted, and the transmission zero of 4.25 GHz is adjusted lower than the transmission zero of 2.45 GHz, and the input power is transmitted as much as possible in the band of 5 GHz or higher, so that it may be set to a value for bandwidth control and frequency suppression.

The antenna module according to the embodiment of the invention is a WiFi module having a Bluetooth and WiFi antenna, and may be applied to a high-frequency module of a mobile phone, a TV receiving a high-frequency signal, and a mobile vehicle.

The features, structures, effects, etc. described in the embodiments above are included in at least one embodiment of the present invention, and are not necessarily limited to only one embodiment. Furthermore, the features, structures, effects, etc. exemplified in each embodiment may be combined or modified and implemented in other embodiments by a person having ordinary knowledge in the field to which the embodiments belong. Therefore, the contents related to such combinations and modifications should be interpreted as being included in the scope of the present invention.

In addition, although the embodiments have been described above, they are merely examples and do not limit the present invention, and a person having ordinary knowledge in the field to which the present invention belongs will understand that various modifications and applications not exemplified above are possible without departing from the essential characteristics of the embodiments. For example, each component specifically shown in the embodiments may be modified and implemented. And the differences related to such modifications and applications should be interpreted as being included in the scope of the present invention defined in the appended claims.

1. An antenna module comprising:
a substrate having a first antenna coupled thereto;
a low-pass filter portion embedded in a portion of the substrate; and
a first transmission line connecting the first antenna and the low-pass filter portion,
wherein the low-pass filter portion includes first to fourth conductive layers, and first to third dielectric layers respectively disposed between the first to fourth conductive layers,
wherein the first conductive layer includes a first pattern having a first via, a second pattern connected between one end of the first pattern and a second via, and a third pattern connected to the third via,
wherein the second conductive layer has a ground pattern having a gap with the first to third vias inside,
wherein the third conductive layer includes a fourth pattern facing the first pattern, and a fifth pattern spaced from the fourth pattern and facing the second via and the third pattern,
wherein the fourth conductive layer includes a sixth pattern connected between the second via inside and a ground via, and a seventh pattern connected between the second via and the third via,
wherein the first pattern and the third pattern of the first conductive layer, the fourth pattern and the fifth patter of the third conductive layer, and the first and second dielectric layers form the first and second capacitors, and
wherein the second pattern, the sixth pattern, and the seventh pattern have a line shape and form the first to third inductors.

2. The antenna module of claim 1,
wherein the first pattern and the third pattern of the first conductive layer, and the fourth pattern and the fifth pattern of the third conductive layer have a polygonal plate shape.

3. The antenna module of claim 2,
wherein an upper surface area of the fifth pattern is smaller than an upper surface area of the third pattern and larger than an upper surface area of the first pattern.

4. The antenna module of claim 3,
wherein the upper surface area of the third pattern is smaller than the upper surface area of the first pattern.

5. The antenna module of claim 4,
wherein the first conductive layer includes a first input/output pattern connected to the other end of the first pattern and the first transmission line, and a second input/output pattern connected to the second pattern and the second transmission line of the other side of the low-pass filter portion.

6. The antenna module of claim 5,
wherein a length of the sixth pattern is longer than a length of the second pattern.

7. The antenna module of claim 6,
wherein a number of bends of the sixth pattern is greater than a number of bends of the second and seventh patterns.

8. The antenna module of & claim 1,
wherein the first capacitor has a first capacitance by the first dielectric layer between the first pattern of the first conductive layer and a first circular pattern connected to the first via of the second conductive layer, and a second capacitance by the second dielectric layer between the first circular pattern and the fourth pattern.

9. The antenna module of claim 1,
wherein the second capacitor is connected to the fifth pattern through the third via connected to the seventh pattern of the fourth conductive layer, a third circular pattern connected to the third via of the second conductive layer, and the third pattern of the first conductive layer,
wherein the second capacitor includes a third capacitance between the third circular pattern and the fourth pattern, and a fourth capacitance by the first dielectric layer between the fifth pattern and the third circular pattern.

10. The antenna module of claim 9,
wherein the second capacitor includes a fifth capacitance by the first dielectric layer between the first via of the first conductive layer and a second circular pattern connected to the second via of the second conductive layer, and a sixth capacitance by the second dielectric layer between the second circular pattern and a fourth circular pattern connected to the second via of the third conductive layer.

11. The antenna module of claim 10,
wherein the third and fifth capacitances are connected in parallel with each other, and the fourth and sixth capacitances are connected in parallel with each other.

12. The antenna module of claim 1, comprising:
a WiFi module connected to the low-pass filter portion and the second transmission line; and
a second antenna connected to the WiFi module,
wherein the first antenna is a Bluetooth antenna,
wherein the second antenna is a WiFi antenna,
wherein the low-pass filter portion passes a 2402 to 2480 MHz band and filters a 5 to 6 GHz band.

13. A high-frequency module comprising:
a low-pass filter portion in which a first input/output pattern is electrically connected to a Bluetooth antenna and a second input/output pattern is electrically connected to a Wi-Fi module,
wherein the low-pass filter portion includes first to fourth conductive layers, dielectric layers respectively disposed between the first to fourth conductive layers, and a plurality of vias that penetrate vertically through the first to fourth conductive layers and the dielectric layers and selectively connect patterns of different conductive layers,
wherein the dielectric layers disposed between one side pattern of the first to third conductive layers and one side pattern of the first to third conductive layers face each other and form a first capacitor connected in parallel to a first branch node connected to the first input/output pattern,
wherein a first line pattern of the first conductive layer forms a first inductor connected in series to the first branch node,
wherein a second line pattern of the fourth conductive layer forms a second inductor connected in parallel from a third branch node connected to the other end of the first inductor,
wherein a third line pattern of the fourth conductive layer forms a third inductor connected in parallel from a second branch node connected to the second input/output pattern and the third branch node, and
wherein the dielectric layers disposed between the other side patterns of the first to third conductive layers and the other side patterns of the first to third conductive layers face each other and form a second capacitor connected in series to the third inductor, and
wherein the other end of the first capacitor, the other end of the second inductor, and the other end of the second capacitor are connected to a ground pattern.

14. The high-frequency module of claim 13, wherein the low-pass filter portion passes a 2402 to 2480 MHz band and filters a 5 to 6 GHz band.

15. The high-frequency module of claim 14,
wherein each of the first to third branch nodes is formed by the vias disposed within the low-pass filter portion.

16. The high-frequency module of claim 13, comprising:
a substrate having the low-pass filter portion,
wherein the first to fourth conductive layers are laminated from an upper surface of the substrate toward a lower surface of the substrate, and
wherein the dielectric layers include first to third dielectric layers respectively disposed between the first to fourth conductive layers.

17. The high-frequency module of claim 16,
wherein a thickness of the second dielectric layer is greater than a thickness of the first dielectric layer.

18. The high-frequency module of claim 16,
wherein the first conductive layer is exposed on the upper surface of the substrate,
wherein the fourth conductive layer is exposed under the lower surface of the substrate.

19. The high-frequency module of claim 16,
wherein a portion of a pattern of the second conductive layer is exposed on a side surface of the substrate.

20. The high-frequency module of claim 16,
wherein the low-pass filter portion has a width between first and third side surfaces on opposite sides smaller than a length between second and fourth side surfaces on opposite sides of the substrate.
